(19) United States
(12) Patent Application Publication
(10) Pub. No.: US 2018/0097340 A1
(43) Pub. Date: Apr. 5, 2018

(54) POWER DISTRIBUTED DEVICE

(71) Applicant: ETASIS ELECTRONICS CORPORATION, Taipei City (TW)

(72) Inventors: I-CHIA LEE, TAIPEI CITY (TW); MING-HUI PENG, NEW TAIPEI CITY (TW); YUNG-SHEN CHANG, NEW TAIPEI CITY (TW)

(21) Appl. No.: 15/708,099

(22) Filed: Sep. 18, 2017

(30) Foreign Application Priority Data
Oct. 5, 2016 (TW) 105215117

(51) Int. Cl. H02B 1/20; H02B 1/26; H05K 7/14; H02H 7/22

(52) U.S. Cl. CPC H02B 1/20; H02B 1/26; H05K 7/1497; H02H 7/22; H05K 7/1427

(57) ABSTRACT

A power distributed device provides a plurality of DC power outputs served as the power required by many servers and many data storage devices. The power distributed device includes a plurality of power supplies. These power supplies are coupled to an AC power input end to receive power from a utility power. The power distributed device also includes a control circuit board, and there are wirings configured on the control circuit board. A power bus bar, a power detection and protection unit, a digital control unit, a communication unit and a plurality of DC power output circuits are configured on the control circuit board. An external control switch is configured at the output end of each DC power output circuit, so that each DC power output circuit can be independently turned on or turned off.

### BACKGROUND OF THE INVENTION

### 1. Field of the Invention

The present disclosure relates to a power distributed device; in particular, to a power distributed device that can be configured in a server room and can provide a plurality of DC power outputs.

### 2. Description of Related Art

Usually, in a server room, a DC power supply should be configured in each server device to provide a DC power required by the server device. Therefore, in one server room, a lot of DC power supplies are needed. Alternatively, there may not be many DC power supplies configured in the server room, but a lot of copper strips should be mounted in the server room for transmitting power to different server devices. The copper strips are large, and the maintenance and repair to them are costly. In addition, the power leakage may be a problem when transmitting power through the copper strips.

### SUMMARY OF THE INVENTION

The present disclosure provides a power distributed device. This power distributed device includes an AC power input end, a plurality of power supplies and a control circuit board. The AC power input end is coupled to a utility power. The power supplies are coupled to the AC power input end. The control circuit board is coupled to the control circuit board. Lots of wirings are configured on the control circuit board and the control circuit board includes a power bus bar, a power detection and protection unit, a digital control unit, a communication unit and a plurality of DC power output circuits. The power bus bar is an input end of the control circuit board to receive the power from the power supplies. The power detection and protection unit is coupled to the power bus bar. The power detection and protection unit detects a plurality of power outputs and executes a protection mechanism related to the power outputs. The digital control unit is coupled to the power detection and protection unit. The digital control unit controls the operation of the power distributed device and outputs a plurality of control signals. The communication unit is coupled to the digital control unit and configured for a wired communication or a wireless communication. Input ends of the DC power output circuits are coupled to the power detection and protection unit, and output ends of the DC power output circuits are coupled to the digital control unit. The DC power output circuits provide a multi-channel power output.

In one of embodiment of the power distributed device provided by the present disclosure, the control signal from the digital control unit is to control the operation of the power supplies and to control operation of the communication unit.

In one of embodiment of the power distributed device provided by the present disclosure, an external control switch is configured at the output end of each DC power output circuit to turn on or turn off the output end of each DC power output circuit.

In one of embodiment of the power distributed device provided by the present disclosure, an output indication light is configured at the output end of each DC power output circuit to indicate the status of each DC power output circuit.

In one of embodiment of the power distributed device provided by the present disclosure, the communication unit includes a system manage bus bar, a Wi-Fi unit, a Bluetooth unit, a RJ45 unit and a USB unit, and the communication unit is coupled to a communication bus bar.

The present disclosure provides another power distributed device. This power distributed device includes a housing, an AC power input end, a plurality of power supplies and a control circuit board. The housing has a front end and a back end. The AC power input end is configured at the front end of the housing to receive a utility power. Each power supply is coupled to the AC power input end, and a heat spreader is configured within the back end of the housing and at each power supply. The control circuit board is configured within the housing and coupled to the power supplies. Wirings are configured on the control circuit board, and the control circuit board includes a power bus bar, a power detection and protection unit, a digital control unit, a communication unit and a plurality of DC power output circuits. The power bus bar is an input end of the control circuit board to receive the power from the power supplies. The power detection and protection unit is coupled to the power bus bar. The power detection and protection unit detects a plurality of power outputs and executes a protection mechanism related to the power outputs. The digital control unit is coupled to the power detection and protection unit. The digital control unit controls the operation of the power distributed device and outputs a plurality of control signals. The communication unit is coupled to the digital control unit and configured for a wired communication or a wireless communication. Input ends of the DC power output circuits are coupled to the power detection and protection unit, and output ends of the DC power output circuits are coupled to the digital control unit. The DC power output circuits provide a multi-channel power output. The output ends of the DC power output circuits are configured at the front end of the housing, and an external control switch and an output indication light are configured at the output end of each DC power output circuit.

In one of embodiment of the power distributed device provided by the present disclosure, a power switch, a USB port, a dissipating device, a plurality of Internet ports and a plurality of indication lights are configured at the front end of the housing. The communication unit includes a system manage bus bar, a Wi-Fi unit, a Bluetooth unit, a RJ45 unit and a USB unit. The communication unit is coupled to a communication bus bar.

The present disclosure provides another power distributed device, and the power distributed device is configured in a frame structure. The power distributed device is similar to any of the above described power distributed devices. A plurality of servers and a plurality of data storage devices are configured in the frame structure, and the servers and the data storage devices receive power from the DC power output circuits of the power distributed device.

The present disclosure provides another power distributed device, and the power distributed device is connected to a power supply circuit. The power distributed device is similar to any of the above described power distributed devices. The power supply circuit includes a plurality of DC power conversion units and a power conversion unit, and the DC power conversion units receive the power from any of the DC power output circuits of the power distributed device. The power conversion unit is coupled to the DC power conversion units, and an output end of the power conversion unit is an output end of the power supply circuit.

The present disclosure provides yet another power distributed device, and the power distributed device is connected to a power supply circuit. The power distributed device is similar to any of the above described power distributed devices. The power supply circuit includes a power supply, a DC power conversion unit and a power conversion unit. The power supply receives a utility power, and the DC power conversion unit receives power from any of the DC power output circuits of the power distributed device. The power conversion unit is coupled to the power supply and the DC power conversion unit, and an output end of the power conversion unit is an output end of the power supply circuit.

To sum up, the present disclosure integrates a plurality of power supplies. The present disclosure has a plurality of DC output ends. An external control switch is configured at the output end of each DC power output circuit, so each DC power output circuit can be independently turned on or turned off. The present disclosure is used in DC power supply devices, and it can help to save energy and reduce carbon emission.

For further understanding of the present disclosure, reference is made to the following detailed description illustrating the embodiments of the present disclosure. The description is only for illustrating the present disclosure, not for limiting the scope of the claim.

### BRIEF DESCRIPTION OF THE DRAWINGS

Embodiments are illustrated by way of example and not by way of limitation in the figures of the accompanying drawings, in which like references indicate similar elements and in which:

FIG. 1 shows a block diagram of a power distributed device according to one embodiment of the present disclosure;

FIG. 2 shows a front view of a power distributed device according to one embodiment of the present disclosure;

FIG. 3 shows a back view of a power distributed device according to one embodiment of the present disclosure;

FIG. 4 shows a schematic drawing of a power distributed device according to the first embodiment of the present disclosure;

FIG. 5 shows a schematic drawing of a power distributed device according to the second embodiment of the present disclosure; and

FIG. 6 shows a schematic drawing of a power distributed device according to the third embodiment of the present disclosure.

### DETAILED DESCRIPTION OF EXEMPLARY EMBODIMENTS

The aforementioned illustrations and following detailed descriptions are exemplary for the purpose of further explaining the scope of the present disclosure. Other objectives and advantages related to the present disclosure will be illustrated in the subsequent descriptions and appended drawings. In these drawings, like references indicate similar elements.

It will be understood that, although the terms first, second, third, and the like, may be used herein to describe various elements, these elements should not be limited by these terms. These terms are only to distinguish one element from another element, and the first element discussed below could be termed a second element without departing from the teachings of the instant disclosure. As used herein, the term “and/or” includes any and all combinations of one or more of the associated listed items.

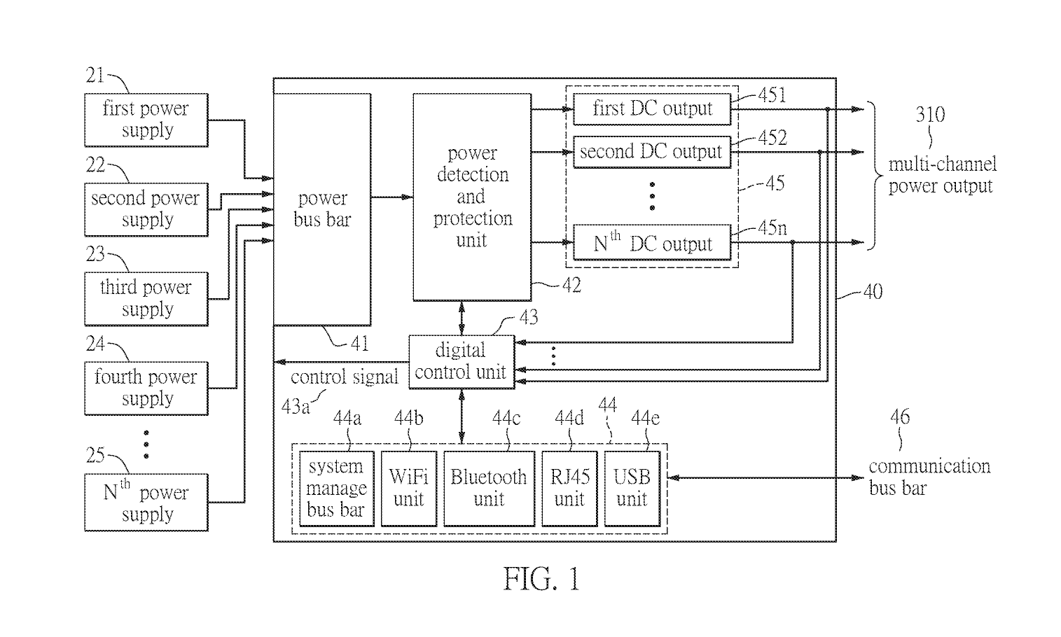

A power distributed device 1 has a control circuit board 40, and can provide a plurality of DC power outputs to be the power required by a plurality of servers and a plurality of data storage devices. FIG. 1 shows a block diagram of a power distributed device according to one embodiment of the present disclosure. As shown in FIG. 1, the power distributed device 1 has a plurality of power supplies. For example, there are five power supplies, which are a first power supply 21, a second power supply 22, a third power supply 23, a fourth power supply 24 and a fifth power supply 25. It should be noted that, the number of power supplies in this embodiment is not limited. The first power supply 21, the second power supply 22, the third power supply 23, the fourth power supply 24 and the fifth power supply 25 receive power from a AC power input end 30. The AC power input end 30 is coupled to a utility power. It is worth mentioning that, in practice, the number of the power supplies is designed to be “N+1”. If N power supplies are actually required, there will be N+1 power supplies configured in the circuit of the power distributed device 1.

In FIG. 1, the control circuit board 40 is coupled to the first power supply 21, the second power supply 22, the third power supply 23, the fourth power supply 24 and the fifth power supply 25. Wirings are designed on the control circuit board 40 to connect different circuit elements configured on the control circuit board 40. The control circuit board 40 includes a power bus bar 41, a power detection and protection unit 42, a digital control unit 43, a communication unit 44 and a plurality of DC power output circuits 45.

The power bus bar 41 controls the input end of the control circuit board 40 to receive power from the first power supply 21, the second power supply 22, the third power supply 23, the fourth power supply 24 and the fifth power supply 25. The power detection and protection unit 42 is coupled to the power bus bar 41 to detect the power from the first power supply 21, the second power supply 22, the third power supply 23, the fourth power supply 24 and the fifth power supply 25, and to execute a protection mechanism related to these power outputs. The digital control unit 43 is coupled to the power detection and protection unit 42 to control operation of the power distributed device 1 and output a plurality of control signals 43a. The circuit operation of the first power supply 21, the second power supply 22, the third power supply 23, the fourth power supply 24 and the fifth power supply 25 is controlled according to the control signals 43a. When the output voltage of one of the power supplies abnormally rises, the power supply will be turned off according to the control signal 43a. The communication unit 44 is coupled to the digital control unit 43 for a wired communication or a wireless communication. The input ends of the DC power output circuits 45 are coupled to the power detection and protection unit 42, and the output ends of the DC power output circuits 45 are coupled to the digital control unit 43. The power outputted by the DC power output circuits 45 are fed back to the digital control unit 43 and further to the power detection and protection unit 42, such that the power detection and protection unit 42 can do a corresponding control. The DC power output circuits 45 provide a multi-channel power output 310. In addition to the circuit operation of the power supplies, the operation of the communication unit 44 is controlled according to the control signals 43a.

The communication unit 44 includes a system manage bus bar, a Wi-Fi unit, a Bluetooth unit, a RJ45 unit and a USB unit. The communication unit 44 is coupled to a communication bus bar 46. Thus, the power distributed device 1 can communicate in a wired way with the server or the data storage device, and the user can also remotely monitor and control the power distributed device 1 in a wireless way. In this embodiment, the DC power output circuits 45 includes a first DC power output circuit 451, a second DC power output circuit 452, . . . , a n^{th} DC power output circuit 45n. The number of the DC power output circuits 45 is not limited and can be designed based on practical needs. In addition, an external control switch 32 is configured at the output end of each of the DC power output circuits 451˜45n to independently turn on or turn off the first DC power output circuit 451, the second DC power output circuit 452, . . . , or the n^{th} DC power output circuit 45n. Moreover, an output indication light 33 is configured at the output end of each of the DC power output circuits 451˜45n to indicate the status of the first DC power output circuit 451, the second DC power output circuit 452, . . . , or the n^{th} DC power output circuit 45n by colors.

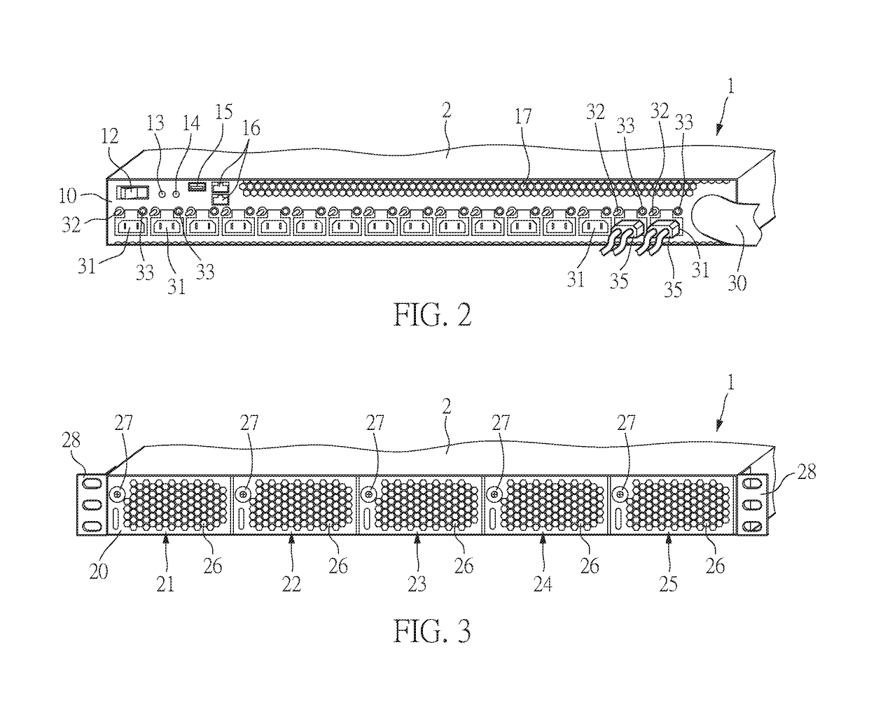

FIG. 2 shows a front view of a power distributed device according to one embodiment of the present disclosure, and FIG. 3 shows a back view of a power distributed device according to one embodiment of the present disclosure. As shown in FIG. 2 and FIG. 3, the circuit shown by FIG. 1 is configured within a housing 2. The housing 2 has a front end 10 and a back end 20. The AC power input end 30 is configured at the front end of the housing 2 to receive a utility power. A heat spreader 26 is configured within the back end 20 of the housing 2 and at each of the first power supply 21, the second power supply 22, the third power supply 23, the fourth power supply 24 and the fifth power supply 25. A plurality of DC output ends 31 are configured at the front end 10 of the housing 2, and the DC output ends 31 correspond to the DC power output circuits 45 of the control circuit board 40. An external control switch 32 and an output indication light 33 are configured at each of the DC output ends 31. The external control switches 32 make each of the DC power output circuits 45 can be independently turned on or turned off. The output indication lights 33 indicate the status of the DC power output circuits 45 by colors. For example, two DC power lines 35 can be connected to the DC output ends 33 to transmit DC power to devices, such as a server or a data storage device.

In FIG. 2, a power switch 12, a USB port 15, a dissipating device 17, a plurality of Internet ports 16 and a plurality of indication lights 13 and 14 are configured at the front end 10 of the housing 2. By using the power switch 12, the power distributed device 1 can be turned on or turned off. Through the USB port 15, a USB device can be connected to the power distributed device 1 so that the USB signal transmission and USB signal control and process can be implemented. The dissipating device 17 is mesh-shaped such that the heat generated during the operation of the power distributed device 1 can be dissipated. Through the Internet ports 16, Internet cables can be connected to the power distributed device 1. The indication lights 13 and 14 indicate the use status of the USB port 15 or the Internet ports 16.

In FIG. 3, the output ends of the first power supply 21, the second power supply 22, the third power supply 23, the fourth power supply 24 and the fifth power supply 25 are configured at the back end 20 of the housing 2. A screwing member 27 is configured on the heat spreader 26 at the output end of each of the first power supply 21, the second power supply 22, the third power supply 23, the fourth power supply 24 and the fifth power supply 25 to make the output ends of the first power supply 21, the second power supply 22, the third power supply 23, the fourth power supply 24 and the fifth power supply 25 fix on the back end 20 of the housing 2. Fasteners 28 are configured respectively at the left side and the right side of the back end 20 of the housing 2. By using the fasteners 28, the power distributed device 1 can be fixed within a frame structure 51 of a machine room.

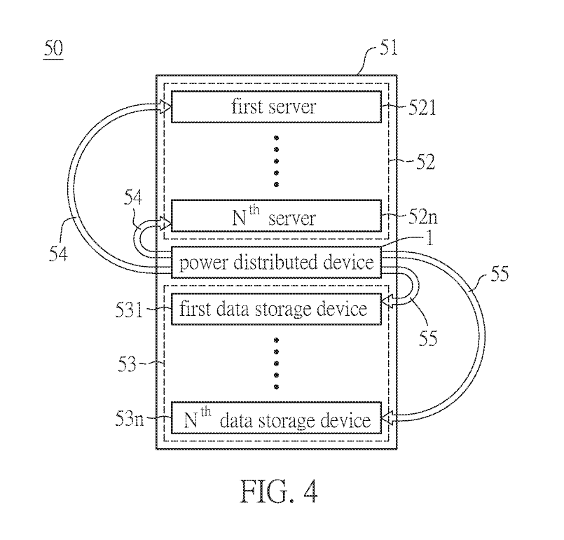

FIG. 4 shows a perspective drawing of a power distributed device according to the first embodiment of the present disclosure. As shown in FIG. 4, the power distributed device 1 is configured in a machine room, such as a machine room for servers or data storage devices. In this embodiment, a system device 50 is configured in a machine room, and the system device 50 has a frame structure 51. For example, the frame structure 51 can be made of metals and has different accommodating rooms for different devices. In FIG. 4, a plurality of servers 52, a plurality of data storage devices 53 and the power distributed device 1 are configured in the frame structure 51. In this embodiment, there are n servers 52, and the servers 52 include a first server 521, . . . , and a n^{th} server 52n. The first server 521, . . . , and the n^{th} server 52n are respectively coupled to the power distributed device 1 by a power line 24, and the power required by each of the first server 521, . . . , and the n^{th} server 52n is provided by the power distributed device 1. In this embodiment, there are n data storage devices. The data storage devices 531˜53n are coupled respectively to the DC output ends 31 of the power distributed device 1 to receive the power they need.

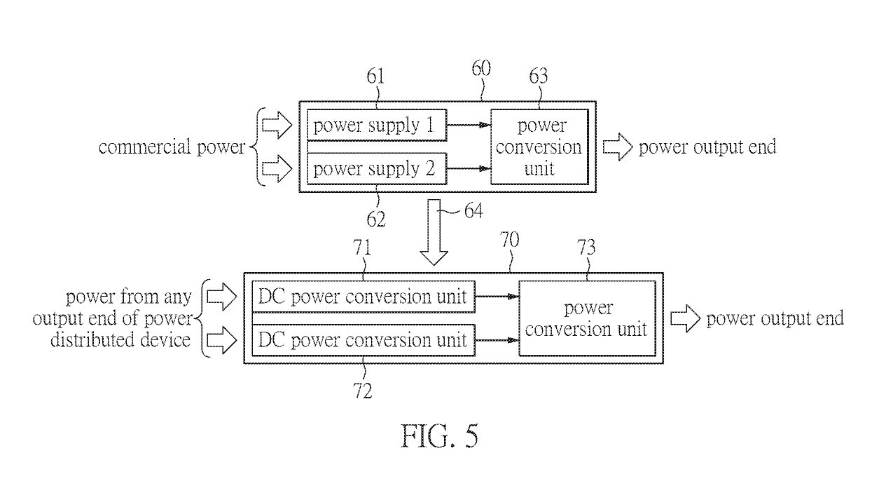

FIG. 5 shows a perspective drawing of a power distributed device according to the second embodiment of the present disclosure. As shown in FIG. 5, a conversion 64 makes a conventional power supply circuit 60 become a power supply circuit 70 using the power distributed device 1. The conventional power supply circuit 60 includes a first power supply 61, a second power supply 62 and a power conversion unit 63. The first power supply 61 and the second power supply 62 are both coupled to the power conversion unit 63, and the first power supply 61 and the second power supply 62 respectively receive a utility power as their input power. The output end of the power conversion unit 63 is a power output end of the conventional power supply circuit 60.

The conversion 64 in FIG. 5 indicates that the power distributed device 1 can be used in a conventional power supply circuit 60, and thus the conventional power supply circuit 60 is converted into a power supply circuit 70 using the power distributed device 1. The power supply circuit 70 includes two DC power conversion units 71 and 72 and a power conversion unit 73. The DC power conversion units 71 and 72 receive power from any of the DC power output circuits of the power distributed device 1. The DC power conversion units 71 and 72 are both coupled to the power conversion unit 73. The output end of the power conversion unit 73 is a power output end of the power supply circuit 70. Unlike the conventional power supply circuit 60 directly receiving a utility power, the power supply circuit 70 receives power from the DC power output circuits of the power distributed device 1.

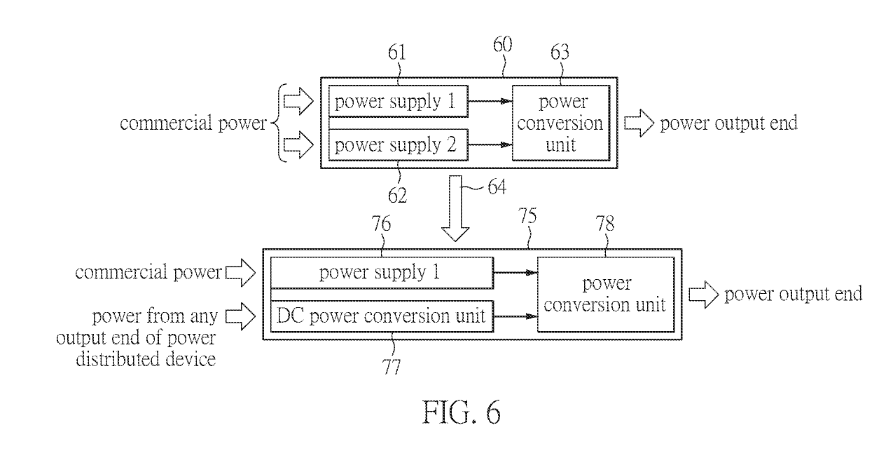

FIG. 6 shows a perspective drawing of a power distributed device according to the third embodiment of the present disclosure. As shown in FIG. 6, a conversion 64 makes a conventional power supply circuit 60 become a power supply circuit 75 using the power distributed device 1. The conventional power supply circuit 60 in this embodiment is similar to the conventional power supply circuit 60 in FIG. 5. The power supply circuit 75 includes a first power supply 76, a DC power conversion unit 77 and a power conversion unit 78. The first power supply 76 receives a utility power. The DC power conversion unit 77 receives power from any of the DC power output circuits of the power distributed device 1 shown in FIG. 1. The first power supply 76 and the DC power conversion unit 77 are both coupled to the power conversion unit 78. The output end of the power conversion unit 78 is a power output end of the power supply circuit 75. In this manner, the utility power and the power from any of the DC power output circuits of the power distributed device 1 can both be the input power of the power supply circuit 75.

To sum up, the present disclosure provides a power distributed device. This power distributed device integrates a plurality of power supplies 21˜25 and has a plurality of DC power output circuits. Through power lines 54 and 55, power can be transmitted to a plurality of servers 52 and a plurality of data storage devices 53. An external control switch 32 is configured at each DC power output circuit, so each DC power output circuit can be independently turned on or turned off. The power distributed device provided by the present disclosure is used in DC power supply devices to make power used efficiently. Also, the power distributed device provided by the present disclosure can be used in an uninterruptible power supply system to help to save energy and reduce carbon emission.

The descriptions illustrated supra set forth simply the preferred embodiments of the present disclosure; however, the characteristics of the present disclosure are by no means restricted thereto. All changes, alterations, or modifications conveniently considered by those skilled in the art are deemed to be encompassed within the scope of the present disclosure delineated by the following claims.

What is claimed is:

1. A power distributed device, comprising:
an AC power input end, coupled to a utility power;
a plurality of power supplies, wherein each of the power supplies is coupled to the AC power input end; and
a control circuit board, coupled to the control circuit board, wherein wirings are configured on the control circuit board and the control circuit board includes:
a power bus bar, being an input end of the control circuit board to receive the power from the power supplies;
a power detection and protection unit, coupled to the power bus bar, detecting a plurality of power outputs and executing a protection mechanism related to the power outputs;
a digital control unit, coupled to the power detection and protection unit, controlling the operation of the power distributed device and outputting a plurality of control signals;
a communication unit, coupled to the digital control unit and configured for a wired communication or a wireless communication; and
a plurality of DC power output circuits, wherein input ends of the DC power output circuits are coupled to the power detection and protection unit, output ends of the DC power output circuits are coupled to the digital control unit, and the DC power output circuits provide a multi-channel power output.

2. The power distributed device according to claim 1, wherein the control signal from the digital control unit is to control the operation of the power supplies and to control the operation of the communication unit.

3. The power distributed device according to claim 1, wherein an external control switch is configured at the output end of each of the DC power output circuits to turn on or turn off each of the DC power output circuits.

4. The power distributed device according to claim 1, wherein an output indication light is configured at the output end of each of the DC power output circuits to indicate the status of each of the DC power output circuits.

5. The power distributed device according to claim 1, wherein the communication unit includes a system manage bus bar, a Wi-Fi unit, a Bluetooth unit, a RJ45 unit and a USB unit, and the communication unit is coupled to a communication bus bar.

6. The power distributed device according to claim 1, connected to a power supply circuit, wherein the power supply circuit includes a plurality of DC power conversion units and a power conversion unit, the DC power conversion units receive power from any of the DC power output circuits of the power distributed device according to claim 1, the power conversion unit is coupled to the DC power conversion units, and an output end of the power conversion unit is an output end of the power supply circuit.

7. The power distributed device according to claim 1, connected to a power supply circuit, wherein the power supply circuit includes a power supply, a DC power conversion unit and a power conversion unit, the power supply receives a utility power, the DC power conversion unit receives power from any of the DC power output circuits of the power distributed device according to claim 1, the power conversion unit is coupled to the power supply and the DC power conversion unit, and an output end of the power conversion unit is an output end of the power supply circuit.

8. A power distributed device, comprising:
a housing, having a front end and a back end;
an AC power input end, configured at the front end of the housing to receive a utility power;
a plurality of power supplies, wherein each of the power supplies is coupled to the AC power input end, and a heat spreader is configured within the back end of the housing and on each of the power supplies; and
a control circuit board, configured within the housing, coupled to the power supplies, wherein wirings are configured on the control circuit board and the control circuit board includes:
a power bus bar, being an input end of the control circuit board to receive power from the power supplies;
a power detection and protection unit, coupled to the power bus bar, detecting a plurality of power outputs and executing a protection mechanism related to the power outputs;
a digital control unit, coupled to the power detection and protection unit, controlling the operation of the power distributed device and outputting a plurality of control signals;
a communication unit, coupled to the digital control unit and configured for a wired communication or a wireless communication; and
a plurality of DC power output circuits, wherein input ends of the DC power output circuits are coupled to the power detection and protection unit, output ends of the DC power output circuits are coupled to the digital control unit, and the DC power output circuits provide a multi-channel power output;
wherein the output ends of the DC power output circuits are configured at the front end of the housing, and an external control switch and an output indication light are configured at the output end of each of the DC power output circuits.

9. The power distributed device according to claim 8, wherein a power switch, a USB port, a dissipating device, a plurality of Internet ports and a plurality of indication lights are configured at the front end of the housing, the communication unit includes a system manage bus bar, a Wi-Fi unit, a Bluetooth unit, a RJ45 unit and a USB unit, and the communication unit is coupled to a communication bus bar.

10. The power distributed device according to claim 8, configured in a frame structure, wherein a plurality of servers and a plurality of data storage devices are configured in the frame structure, and the servers and the data storage devices receive power from the DC power output circuits of the power distributed device.
